(19) United States
(12) Patent Application Publication
(10) Pub. No.: US 2009/0165705 A1
(43) Pub. Date: Jul. 2, 2009

(54) Batch forming system for amorphous silicon film

(75) Inventors: Kung-Hsu Yeh, Tainan City (TW); Ming-Hung Huang, Kaohsiung County (TW)

Correspondence Address: BACON & THOMAS, PLLC, 625 SLATERS LANE, FOURTH FLOOR, ALEXANDRIA, VA, 22314-1176, US

(73) Assignee: CONTREL TECHNOLOGY CO., LTD., TAINAN COUNTY (TW)

(21) Appl. No.: 12/213,313

(22) Filed: Jun. 18, 2008

(30) Foreign Application Priority Data
Dec. 31, 2007 (TW) 96151590

(51) Int. Cl. C23C 14/00

(52) U.S. Cl. 118/50

(57) ABSTRACT

A batch forming system for amorphous silicon films is composed of at least one p-layer formation chamber having a sealing gate that can be opened or closed; at least one i-layer formation chamber having a sealing gate that can be opened or closed; at least one n-layer formation chamber having a sealing gate that can be opened or closed; a common vacuum chamber connected with said formation chambers; a conveyance device having a bearing surface movable to the fronts of said sealing gates respectively; and a cart for carrying a plurality of plate-shaped materials, being allowed passing through said sealing gates to enter said formation chambers respectively from said bearing surface or to exit said formation chambers and then go back to the bearing surface. Therefore, batch forming system can speedy up the production and do the batch formation of a multiplicity of the amorphous silicon films at a time.

### BACKGROUND OF THE INVENTION

1. Field of the Invention

The present invention relates generally to the technology of formation of amorphous silicon films, and more particularly, to a batch forming system for amorphous silicon films.

2. Description of the Related Art

In recent years, people pay more attention to the substitutive energy resources because of the shortage of energy resources and the highly rising price of petroleum. Among the substitutive energy resources, the solar energy has been applied to the solar cell, which can generate electric energy. Because the solar cell is of high environmental protection, it draws much attention and a great amount of research resource.

There are a variety of solar cells, wherein the amorphous solar cell is the mainstream. The amorphous silicon film is essential to production of the amorphous cell. The prevalent approach for production of the amorphous silicon film is plasma-enhanced chemical vapor deposition (PECVD). The amorphous silicon film is formed by deposition of three layers of p-a-Si:H, i-a-Si:H, and n-a-Si:H, i.e. p-i-n.

The current p-i-n film is formed by the steps of placing a deposition receiving member, like glass plate, in a chamber horizontally, then forming a p-layer film, an i-layer film, and an n-layer film in turn, and finally moving the deposit outward. Because the three films in such approach are formed in the same chamber, before the next vapor deposition proceeds, the existing gas must be pumped out of the chamber first, then another gas corresponding to the deposit is infused into the chamber, and the concentration of the gas is well conditioned. However, such approach incurs standby and prolongs the duration of the film formation, thus being unfavorable to speedy production.

### SUMMARY OF THE INVENTION

The primary objective of the present invention is to provide a batch forming system for amorphous silicon films, wherein various types of the amorphous films are processed separately in the system for speedier production.

The secondary objective of the present invention is to provide a batch forming system for amorphous silicon films, wherein a multiplicity of the amorphous silicon films can be formed in batch at a time.

The foregoing objectives of the present invention are attained by the batch forming system composed of at least one p-layer formation chamber, at least one i-layer formation chamber, at least one n-layer formation chamber, a common vacuum chamber, a conveyance device, and a cart. The p-layer formation chamber is provided for deposition of a layer of a p-type amorphous silicon film on a plate-shaped material, having a sealing gate that can be opened or closed. The i-layer formation chamber is provided for deposition of an i-type amorphous film on the plate-shaped material, having a sealing gate that can be opened or closed. The n-layer formation chamber is provided for deposition of an n-type amorphous film on the plate-shaped material, having a sealing gate that can be opened or closed. The common vacuum chamber is connected with the p-layer, i-layer, and n-layer formation chambers and can be in communication with or isolated from each other in such a way that the sealing gates are opened or closed. The conveyance device is movable and located in the common vacuum chamber, having a bearing surface that can be located in front of the sealing gates of the formation chambers respectively when the conveyance device is moved. The cart is located on the bearing surface of the conveyance device for carrying a plurality of plate-shaped materials. The cart is located on the bearing surface of the conveyance device and movable through the sealing gates to enter or exit the formation chambers respectively.

### BRIEF DESCRIPTION OF THE DRAWINGS

FIG. 1 is a schematic view of a first preferred embodiment of the present invention.

FIG. 2 is another schematic view of the first preferred embodiment of the present invention in operation.

FIG. 3 is another view of the first preferred embodiment of the present invention in operation.

FIG. 4 is a schematic view of a second preferred embodiment of the present invention.

FIG. 5 is a schematic view of a third preferred embodiment of the present invention.

FIG. 6 is a schematic view of a fourth preferred embodiment of the present invention.

FIG. 7 is a schematic view of a fifth preferred embodiment of the present invention.

### DETAILED DESCRIPTION OF PREFERRED EMBODIMENTS

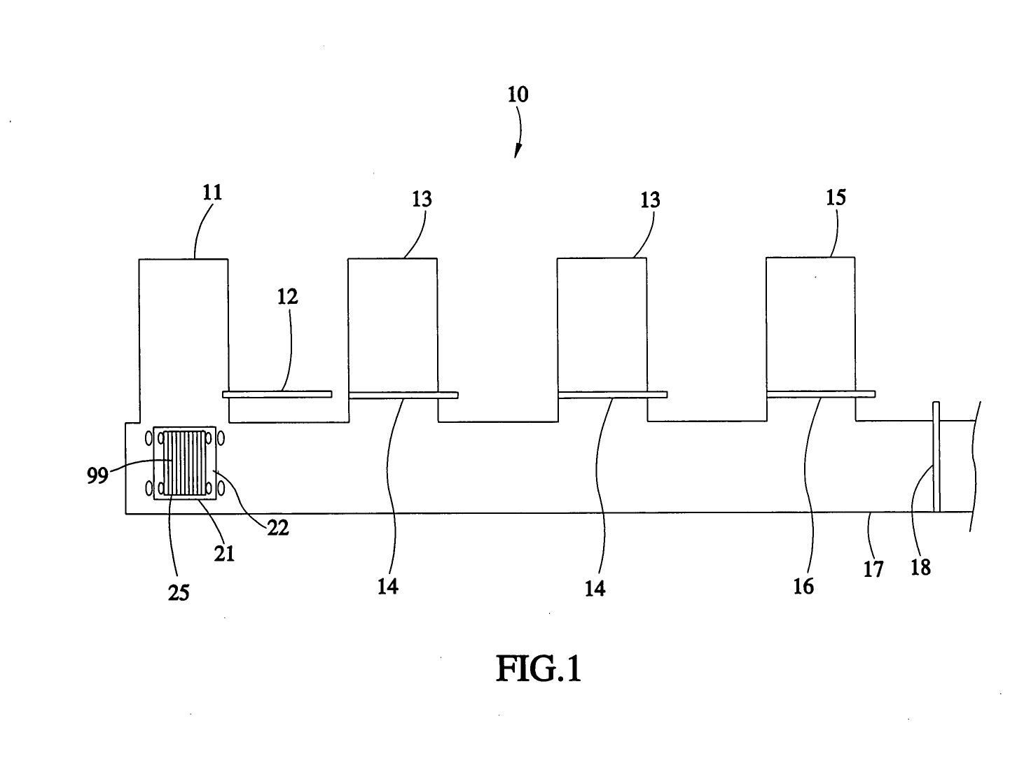

Referring to FIG. 1, a batch forming system 10 for amorphous silicon films in accordance with a first preferred embodiment of the present invention is composed of a p-layer formation chamber 11, two i-layer formation chambers 13, a n-layer formation chamber 15, a common vacuum chamber 17, a conveyance device 21, and a cart 25.

The p-layer formation chamber 11 is provided for deposition of a p-type amorphous film (not shown) on a plate-shaped material 99, like glass substrate, and includes a sealing gate 12 that can be opened or closed.

The two i-layer formation chambers 13 are provided for deposition of an i-type amorphous film (not shown) on the plate-shaped material 99 and each include a sealing gate 13 that can be opened or closed.

The n-layer formation chamber 15 is provided for deposition of an n-type amorphous film (not shown) on the plate-shaped material 99 and includes a sealing gate 16 that can be opened or closed.

The formation chambers 11, 13 & 15 are arranged in the sequence of p-i-i-n; in this embodiment, they are arrayed linearly and all of the sealing gates 12, 14 & 16 face the same direction.

The common vacuum chamber 17 is connected with the p-layer, i-layer, and n-layer formation chambers 11, 13 & 15 and can be in communication with or isolated from them respectively in such a way that the respective sealing gates 12, 14 & 16 are opened or closed. The common vacuum chamber 17 includes an incoming and outgoing gate 18 for communication with or isolation from the outside. When the incoming and outing gate 18 is opened, the conveyance device 21 or the cart 25 can enter the common vacuum chamber 17.

The conveyance device 21 is a movable trolley located in the common vacuum 1, having a bearing surface 22 on a top side thereof. The conveyance device 21 is movable to allow the bearing surface 22 being located in front of the sealing gates 12, 14 & 16 respectively.

The cart 25 for carrying a plurality of the plate-shaped materials 99 is located on the bearing surface 22 of the conveyance device 21. The plate-shaped materials 99 are upright and spaced from each other in a predetermined interval. The cart 25 is movable through the sealing gates 12, 14 & 16 respectively to enter the formation chambers 11, 13 & 15 from the bearing surface 22 or to exit the formation chambers 11, 13 & 15 to go back to the bearing surface 22.

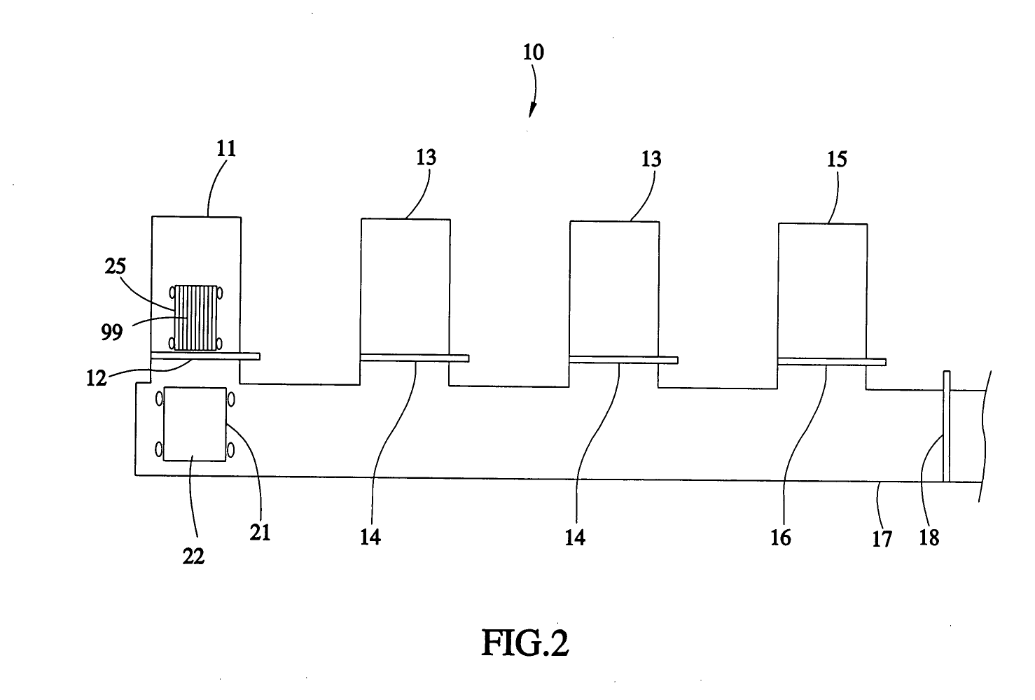

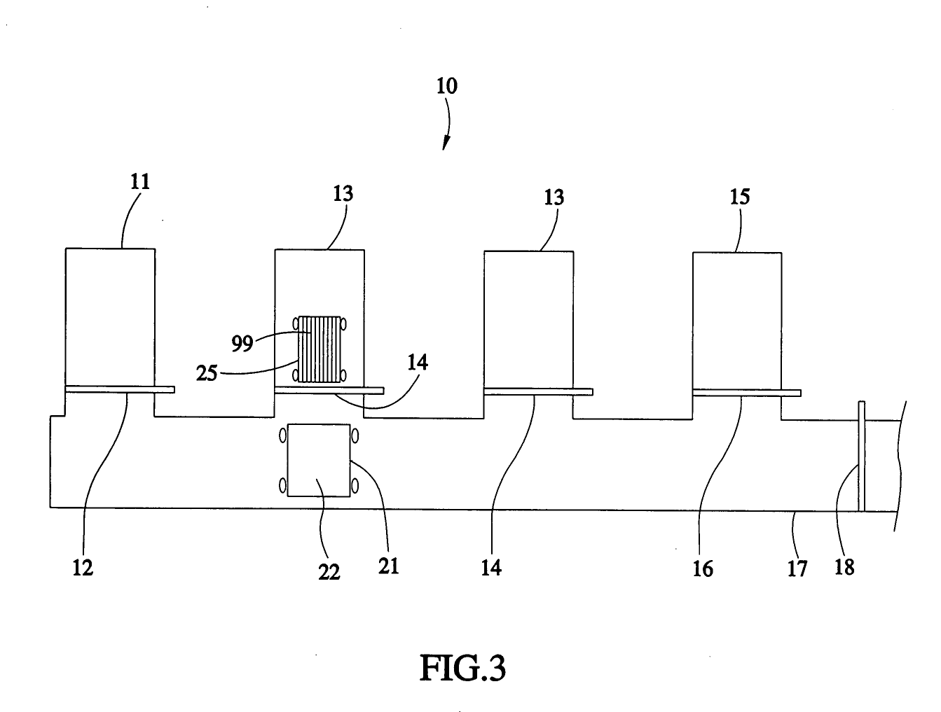

The present invention can operated as recited as follows. Referring to FIG. 1 again, the cart 25 carrying the plate-shaped materials 99 is placed on the bearing surface 22 of the conveyance device 21. In the meantime, the cart 25 is moved to the front of the p-layer formation chamber 11 and the sealing gate 12 is opened. Referring to FIG. 2, the cart 25 enters the p-layer formation chamber 11, and then a PECVD process is done in the p-layer formation chamber 11. Therefore, a layer of a p-type amorphous silicon film (not shown) of a predetermined thickness is deposited on the plate-shaped materials 99. Referring to FIG. 3, after the p-type amorphous silicon film is formed, the cart 25 exits the p-layer formation chamber 11 to go back to the conveyance device 21, and then the conveyance 25 carries the cart 25 to move to the front of the i-layer formation chamber 13. Next, the cart 25 enters the i-layer formation chamber in the same way mentioned above and then a layer of i-type amorphous silicon film (not shown) is deposited by the same way mentioned above. After the aforementioned steps are repeated, different types of the amorphous silicon films as required are formed in the respective formation chambers 11, 13 & 15. Finally, a p-i-n amorphous silicon film is accomplished.

There are two i-layer formation chambers 13 because the i-type amorphous silicon film requires more thickness, during the production of the p-i-n amorphous silicon film, to need more time. Therefore, two or more i-layer formation chambers 13 can be provided to facilitate reduction of standby time of the other plate-shaped materials 99.

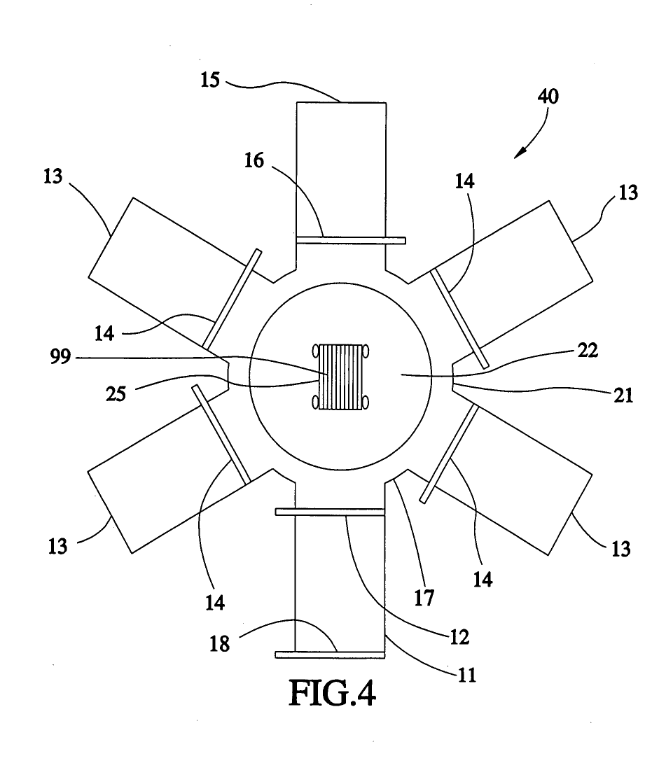

Referring to FIG. 4, a batch forming system 40 for amorphous silicon films in accordance with a second preferred embodiment of the present invention is similar to the first embodiment of the present invention, having difference recited below.

The batch forming system 40 includes six formation chambers 11, 13 & 15 arrayed annularly and in the sequence of p-i-i-n-i-i. Each of the sealing gates 12, 14 & 16 faces a center that the formation chambers 11, 13 & 15 surround. The common vacuum chamber 17 is approximately circular. The incoming and outgoing gate 18 is mounted in the p-layer formation chamber 11. The conveyance device 21 is a turntable, whose top side is the bearing surface 22.

When the batch forming system 40 is operated, the cart 25 is moved to the front of one of the formation chambers 11, 13 & 15 by the rotation of the conveyance device 21 and then enters the formation chamber 11, 13 or 15. After the cart 25 exits the formation chamber 11, 13 or 15, the cart 25 goes back to the conveyance device 21 and then moves to the front of another formation chamber 11, 13 or 15. When it is intended to deliver the plate-shaped materials 99, the conveyance device 21 can do it by passing through the incoming and outgoing gate 18 to enter or exits the p-layer formation chamber 11. In addition, the incoming and outgoing gate 18 can be alternatively mounted in the n-layer formation chamber 16 and can be operated in the same way, such that no more description is necessary. The conveyance device 21 can alternatively be a movable trolley to attain the same rotational effect as the turntable does. Because the shape of the turntable has been shown in FIGS. 1-3, no more drawings showing the turntable are necessary. The other structural features and operations of the second embodiment are identical to those of the first embodiment, so more recitation of them is not necessary.

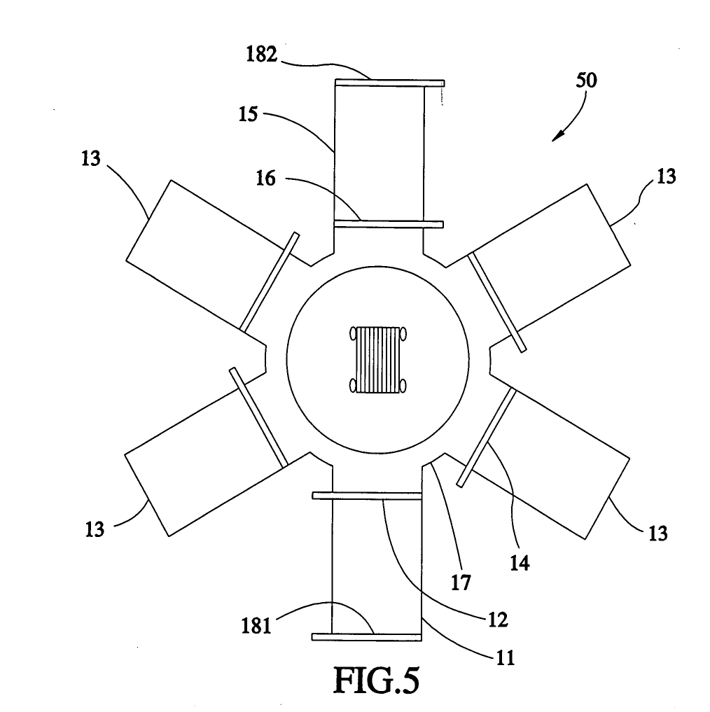

Referring to FIG. 5, a batch forming system 50 for amorphous silicon films in accordance with a third preferred embodiment of the present invention is similar to the second embodiment of the present invention, having difference recited below.

The p-layer formation chamber 11 includes an incoming gate 181 for communication with or isolation from the outside. The n-layer formation chamber 15 includes an outgoing gate 182 for communication with or isolation from the outside. In this way, the materials can pass through the incoming gate 181 to enter the p-layer formation chamber 11, while being delivered inside, and can pass through the outgoing gate 182 to exit the n-layer formation chamber, while being delivered outside. Because the other structural features and operations of the third embodiment are identical to those of the second embodiment, more recitation of them is not necessary.

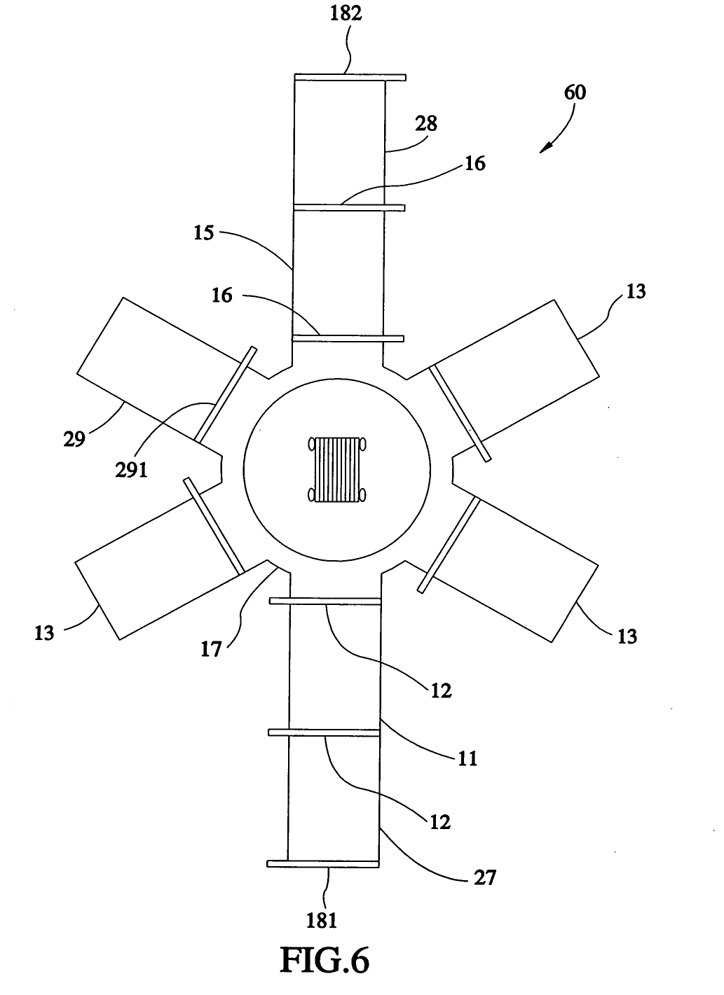

Referring to FIG. 6, a batch forming system 60 for amorphous silicon films in accordance with a fourth preferred embodiment of the present invention is similar to the second embodiment of the present invention, having difference recited below.

The batch forming system 60 further includes an incoming chamber 27, an outgoing chamber 28, and a temporary storage chamber 29. The incoming chamber 27 is connected with the p-layer formation chamber 11. A sealing gate 12 is located between the p-layer formation chamber 11 and the incoming chamber 27. The incoming chamber 27 includes an incoming gate 181 for communication with or isolation from the outside. The outgoing chamber 28 is connected with the n-layer formation chamber 15. A sealing gate 16 is located between the n-layer formation chamber 15 and the outgoing chamber 28. The outgoing chamber 28 includes an outgoing gate 182 for communication with or isolation from the outside. The temporary storage 29 is connected with the common vacuum chamber 17, having a sealing gate 291 for communication with or isolation from the common vacuum chamber 17. In this way, the materials can pass through the incoming gate 181 to enter the incoming chamber 27 and then the p-layer formation chamber 11, while being delivered inside, and can pass through the n-layer formation chamber 15 to enter the outgoing chamber 28 and then the outgoing gate 182, while being delivered outside. The temporary storage chamber 29 is provided for temporary storage of the cart 25, such that the temporary storage chamber 29 can be acted as buffering allocation and transfer of the materials between the formation chambers 11, 13 & 15. Because the other structural features and operations of the fourth embodiment are identical to those of the second embodiment, more recitation of them is not necessary.

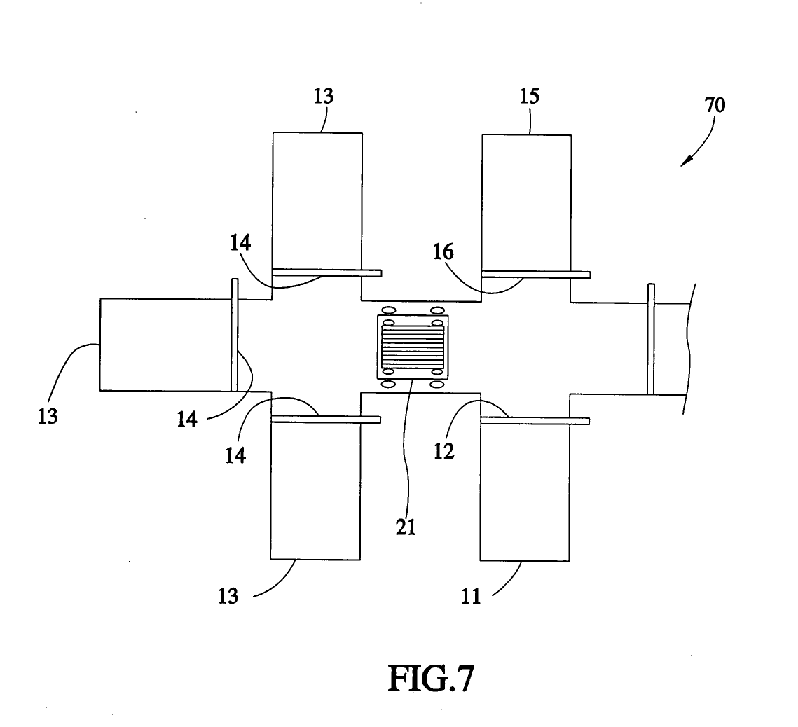

Referring to FIG. 7, a batch forming system 70 for amorphous silicon films in accordance with a fifth preferred embodiment of the present invention is similar to the first embodiment of the present invention, having difference recited below.

The batch forming system 70 includes five formation chambers 11, 13 & 15, two of which face another two thereof. When the two formation chambers face the another two formation chambers, two of the sealing gates 12, 14 & 16 face another two. In this embodiment shown in FIG. 7, two of the i-layer formation chambers 13 face each other and the p-layer formation chamber 11 faces the n-layer formation chamber 15. Besides, each of the two formation chambers facing the another two is spaced from the corresponding one of the another two for a predetermined interval, whereby the conveyance device 21 can pass through the interval. Because the other structural features and operations of the fifth embodiment are identical to those of the first embodiment, more recitation of them is not necessary. In this embodiment, the arrangement of the formation chambers can shorten the path of movement of the conveyance device 21 to attain the time-saving effect.

In conclusion, the present invention includes the following advantages.

1. Speedier Production
Multiple types of the amorphous silicon films can be processed separately to enable each of the formation chambers to process only one type of the amorphous films, such that it avoids the standby of substitution of the gas in the prior art to enhance the speed of the production.

2. Batch Formation for Multiple Materials at a Time
The plate-shaped materials are located upright on the cart and spaced from each other in a predetermined interval to be processed in each of the formation chambers at a time and be delivered by the conveyance device to each of the formation chambers, such that the batch formation for the multiple materials at a time can be done.

Although the present invention has been described with respect to specific preferred embodiments thereof, it is no way limited to the details of the illustrated structures but changes and modifications may be made within the scope of the appended claims.

What is claimed is:

1. A batch forming system for amorphous silicon films, comprising:
at least one p-layer formation chamber for deposition of a p-type amorphous silicon film on a plate-shaped material, said p-layer formation chamber having a sealing gate that can be opened or closed;
at least one i-layer formation chamber for deposition of an i-type amorphous silicon film on said plate-shaped material, said i-layer formation chamber having a sealing gate that can be opened or closed;
at least one n-layer formation chamber for deposition of an n-type amorphous silicon film on said plate-shaped material, said n-layer formation chamber having a sealing gate that can be opened or closed;
a common vacuum chamber connected with said p-layer, i-layer, n-layer formation chambers for communication with or isolation from said p-layer, i-layer, n-layer formation chambers respectively in such a way that said sealing gates are opened or closed respectively;
a conveyance device located in said common vacuum chamber and having a bearing surface, said conveyance device being movable to enable said bearing surface to located in front of said formation chambers respectively; and
a cart located on said bearing surface of said conveyance device for carrying a plurality of plate-shaped materials, said cart being movable through each of said sealing gates to enter the corresponding one of said formation chambers from said bearing surface or to exit said corresponding formation chamber and then go back to said bearing surface.

2. The batch forming system as defined in claim 1, wherein said at least one p-layer formation chamber is one in number, said at least one i-layer formation chamber is two in number, and said at least one n-layer formation chamber is one in number.

3. The batch forming system as defined in claim 2, wherein said formation chambers are arrayed in the sequence of p-i-i-n.

4. The batch forming system as defined in claim 2, wherein said formation chambers are arranged linearly, and each of said sealing gates face the same direction.

5. The batch forming system as defined in claim 2, wherein said formation chambers are arranged annularly, and each of said sealing gates faces a center that said formation chambers surround.

6. The batch forming system as defined in claim 5, wherein said conveyance device is a turntable.

7. The batch forming system as defined in claim 2, wherein two of said formation chambers face another two, and each of said sealing gates of said two formation chambers facing another two faces the corresponding sealing gate of said another two formation chambers.

8. The batch forming system as defined in claim 4 or 5 or 7, wherein said conveyance device is a movable trolley, and said bearing surface is located on a top side of said conveyance device.

9. The batch forming system as defined in claim 1, wherein said plate-shaped materials in said cart are upright and spaced from each other in a predetermined interval.

10. The batch forming system as defined in claim 1 further comprising an incoming and outgoing gate, wherein said incoming and outgoing gate is located at one of said p-layer formation chamber, said n-layer formation chamber, and said common vacuum chamber.

11. The batch forming system as defined in claim 1 further comprising an incoming gate and an outgoing gate, wherein said incoming gate is located at said p-layer formation chamber for communication with or isolation from an outside, and said outgoing gate is located said n-layer formation chamber for communication with or isolation from an outside.

12. The batch forming system as defined in claim 1 further comprising an incoming chamber, an outgoing chamber, two sealing gates, an incoming gate, and an outgoing gate, wherein said incoming chamber is connected with said p-layer formation chamber; one of said sealing gates is located between said p-layer formation chamber and said incoming chamber; said incoming gate is located at said incoming chamber, whereby said incoming chamber can communicate with or be isolated from an outside via said incoming gate; said outgoing gate is connected with said n-layer formation chamber; the other sealing gate is located between said n-layer formation chamber and said outgoing chamber; and said outgoing gate is located at said outgoing chamber, whereby said outgoing chamber can communicate with or be isolated from an outside via said outgoing gate.

13. The batch forming system as defined in claim 1 further comprising a temporary storage chamber, wherein said temporary storage chamber is connected with said common vacuum chamber and has a sealing gate for communication with or isolation from said common vacuum chamber.
